(19) United States
(12) Patent Application Publication
(10) Pub. No.: US 2024/0387408 A1
(43) Pub. Date: Nov. 21, 2024

(54) SEMICONDUCTOR DEVICES, FABRICATION METHODS OF SEMICONDUCTOR DEVICES AND SEMICONDUCTOR APPARATUS

(71) Applicant: Yangtze Memory Technologies Co., Ltd., Wuhan (CN)

(72) Inventors: Wei Xie, Wuhan (CN); Dongyu Fan, Wuhan (CN); Lei Liu, Wuhan (CN); Kun Zhang, Wuhan (CN); Wenxi Zhou, Wuhan (CN); ZhiLiang Xia, Wuhan (CN)

(21) Appl. No.: 18/529,960

(22) Filed: Dec. 5, 2023

(30) Foreign Application Priority Data
May 15, 2023 (CN) 202310546029.9

(51) Int. Cl. H01L 23/58; H01L 21/60

(52) U.S. Cl. CPC H01L 23/585; H01L 21/60; H01L 2021/60127

(57) ABSTRACT

Examples of the present application disclose semiconductor devices, fabrication methods of semiconductor devices, and semiconductor apparatus. In one example, the semiconductor device includes a first die, the first die includes a first bonding layer, wherein the first bonding layer includes a first connection structure and a first metal ring, the first metal ring disposed around the first connection structure.

### CROSS-REFERENCE TO RELATED APPLICATION

This application claims priority to and the benefit of Chinese Patent Application 202310546029.9, filed on May 15, 2023, which is hereby incorporated by reference in its entirety.

### TECHNICAL FIELD

The present application relates to semiconductors, and particularly to semiconductor devices, fabrication methods of semiconductor devices, and semiconductor apparatus.

### BACKGROUND

A hybrid bonding technology is a process of bonding two chips together, and the use of the hybrid bonding technology can greatly reduce chip research and development and manufacturing periods, shorten a metal interconnection between functional chips, and reduce heat, power consumption and delay. However, in a process of bonding two wafers or two chips through the hybrid bonding technology, there are still some problems that need to be further solved.

### BRIEF DESCRIPTION OF THE DRAWINGS

The drawings to be used in description of examples will be briefly introduced below in order to illustrate the technical solutions in the examples of the present application more clearly. The drawings described below are only some examples of the present application. Those having ordinary skill in the art may obtain other drawings according to these drawings without creative work.

FIG. 1 is a schematic structure diagram of one example of a first wafer provided by examples of the present application.

FIG. 2 is a schematic structure diagram of one example of a second wafer provided by examples of the present application.

FIG. 3 is a schematic structure diagram of one example of a first die and a second die provided by examples of the present application.

FIG. 4 is a sectional view of FIG. 3 along an A-A direction.

FIG. 5 is a sectional view of another example of a first die provided by examples of the present application, with a sectioning position being consistent with a sectioning position in FIG. 4.

FIG. 6 is a sectional view of FIG. 3 along a B-B direction.

FIG. 7 is a sectional view of another example of a second die provided by examples of the present application, with a sectioning position being consistent with a sectioning position in FIG. 6.

FIG. 8 is a schematic structure diagram after face-to-face disposing of a first bonding layer of a first die and a second bonding layer of a second die provided by examples of the present application.

FIG. 9 is a schematic structure diagram of one example of a semiconductor apparatus provided by examples of the present application.

FIG. 10 is a sectional view of FIG. 9 along a C-C direction.

FIG. 11 is a sectional view of another example of a semiconductor device provided by examples of the present application, with a sectioning position being consistent with a sectioning position in FIG. 10.

FIG. 12 is a schematic structure diagram of one example of first dies and a first dielectric layer provided by examples of the present application.

FIG. 13 is a schematic structure diagram of one example of second dies and a second dielectric layer provided by examples of the present application.

FIG. 14 is a schematic structure diagram of one example of an electromagnetic induction heater provided by examples of the present application.

FIG. 15 is a flow chart of one example of a fabrication method of a semiconductor device provided by examples of the present application.

The examples described herein utilize the following numbering: Semiconductor apparatus 1; semiconductor device 10; first wafer 11; first die 110; first substrate 111; first circuit layer 112; first bonding layer 113; first connection structure 1131; first connection line 1132; first connection terminal 1133; first surface 1134; first protrusion 1135; first heat preservation portion 1136; first metal ring 1137; first dielectric layer 114; second wafer 12; second die 120; second substrate 121; second circuit layer 122; second bonding layer 123; second connection structure 1231; second connection line 1232; second connection terminal 1233; second surface 1234; second protrusion 1235; second heat preservation portion 1236; second metal ring 1237; second dielectric layer 124; electromagnetic induction heater 20; coil assembly 21; first winding area 211; second winding area 212; base 22.

### DETAILED DESCRIPTION

The technical solutions in examples of the present application will be described below clearly and completely in conjunction with the drawings in the examples of the present application. The examples described are only part of, but not all of, the examples of the present application. All other examples will be understood by those having ordinary skill in the art based on the examples in the present application without creative work shall fall within the scope of protection of the present application. Furthermore, it should be understood that, the detailed description described herein is only used for illustrating and explaining the present application, instead of restricting the present application.

In the present application, in the case where the contrary is not stated, the directional words used, such as “above” and “below” typically refer to above and below of a device in an actual use or working state, specifically in the direction of the page in the drawings, and “inner” and “outer” are directed to the outline of the apparatus.

A hybrid bonding technology is a technology of bonding two semiconductor devices, such as two wafers or two chips, etc., to each other. In a process of bonding two semiconductor devices through the hybrid bonding technology, there is a need to dispose bonding interfaces on the two semiconductor devices oppositely, such that metal layers of the bonding interfaces of the two semiconductor devices are aligned with each other, and dielectric layers of the bonding interfaces of the two semiconductor devices are aligned with each other. Then, the two semiconductor devices are heated, such that the metal layers of the bonding interfaces of the two semiconductor devices are bonded to each other, and the dielectric layers of the bonding interfaces of the two semiconductor devices are bonded to each other.

A temperature required for realizing mutual bonding of the metal layers and the dielectric layers of the bonding interfaces of the two semiconductor devices is high, for example reaches 400° C. to 450° C. Regardless of whether in a process of heating the two semiconductor devices to a high temperature or in a process of performing long-time high-temperature annealing on the two semiconductor devices, it is easy to introduce stress into the two semiconductor devices after the bonding is completed, resulting in the problem of deformation or even fracture of structures inside the two semiconductor devices. Especially, when the semiconductor devices comprise materials that are not resistant to a high temperature, the semiconductor devices will be damaged after bonding the bonding interfaces of the two semiconductor devices at the high temperature.

If the metal layers and the dielectric layers of the bonding interfaces of the two semiconductor devices are bonded at a low temperature, the bonding energy of the bonding interfaces of the two semiconductor devices will be reduced, resulting in low bonding strength and reliability between the two semiconductor devices.

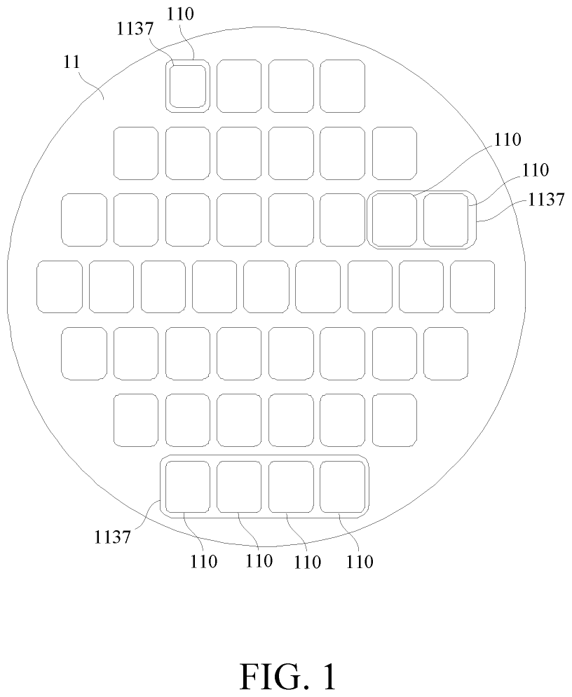

To avoid the above problems, examples of the present application provide a semiconductor device. As shown in FIGS. 1 and 3, the semiconductor device 10 comprises first dies 110 that comprise first bonding layers 113. The first bonding layers 113 of the first dies 110 are configured to bond with other dies (for example, the first bonding layers 113 of the first dies 110 are configured to bond with second bonding layers 123 of second dies 120).

With continued reference to FIGS. 1 and 3, the first bonding layers 113 comprise first connection structures 1131 and first metal rings 1137, wherein each of the first metal rings 1137 is disposed around at least one of the first connection structures 1131. The first connection structures 1131 are configured to bond with connection structures of other dies (for example, the first connection structures 1131 of the first dies 110 are configured to bond with second connection structures 1231 of the second dies 120), such that the first dies 110 are bonded with the other dies (e.g., the second dies 120).

In the semiconductor device 10 provided by examples of the present application, by disposing the first metal rings 1137 each surrounding at least one of the first connection structures 1131 on the first bonding layers 113 of the first dies 110, the first dies 110 may be placed in alternating magnetic field, and current is generated in the first connection structures 1131 in the first dies 110 through the alternating magnetic field, such that the first connection structures 1131 are heated, thereby bonding the first connection structures 1131 of the first dies 110 to the connection structures of the other dies. However, insulating materials of the first dies 110 do not generate current in the alternating magnetic field and are not heated. Therefore, the insulating materials of the first dies 110 can maintain a lower temperature to reduce the risk of deformation or even fracture caused by stress generated due to a high temperature inside the first dies 110 of the semiconductor device 10.

That is, the semiconductor device 10 provided by examples of the present application can achieve heating of the first connection structures 1131 of the first dies 110 to a high temperature, such that the first connection structures 1131 of the first dies 110 can have high bonding strength and reliability after bonding with the connection structures of the other dies. Meanwhile, regions formed by the insulating materials in the first dies 110 can maintain a low temperature to reduce the risk of deformation or even fracture caused by the stress generated due to the high temperature inside the first dies 110.

Moreover, by disposing the first metal rings 1137, the alternating magnetic field can be uniformly distributed within the first metal rings 1137, so as to heat the first connection structures 1131 more uniformly to enable temperature distribution of the first connection structures 1131 to be more uniform, such that the first connection structures 1131 of the first dies 110 are fully connected with the connection structures of the other dies by bonding, thereby further improving the bonding strength and reliability of the first dies 110 and the other dies.

It is to be noted that, each of the first metal rings 1137 may be disposed around the first connection structures 1131 of one of the first dies 110, or disposed around the first connection structures 1131 of a plurality of the first dies 110. For example, as shown in FIG. 1, a first wafer 11 comprises a plurality of first dies 110, such that each of the first metal rings 1137 may be disposed around the first connection structures 1131 of one of the first dies 110, or each of the first metal rings 1137 may also be disposed around the first connection structures 1131 of two, three, four or more of the first dies 110.

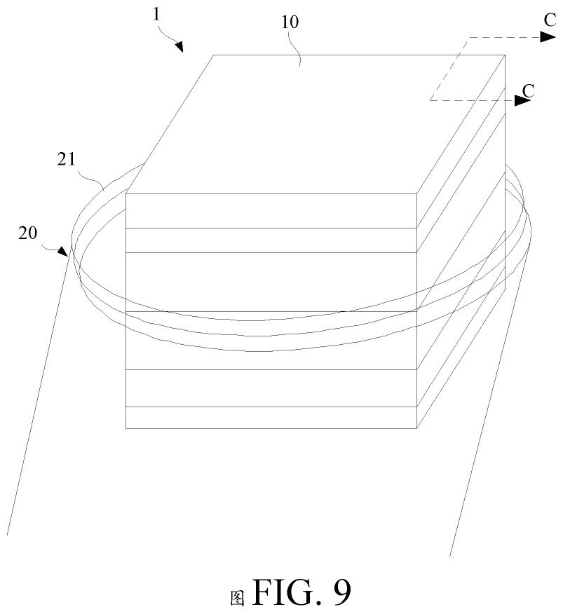

In some examples, as shown in FIG. 9, the first connection structures 1131 may be heated through an electromagnetic induction heater 20. The electromagnetic induction heater 20 may generate alternating magnetic field (also referred to as alternating electromagnetic field or time-varying electromagnetic field) that is perpendicular to the first bonding layers 113 of the first dies 110, such that current is generated within the first connection structures 1131, thereby heating the first connection structures 1131.

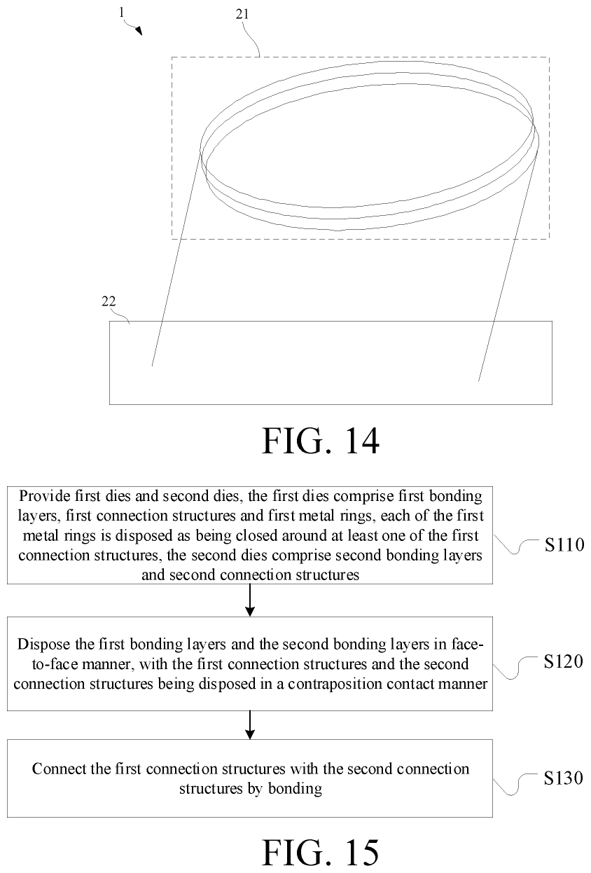

In an example, as shown in FIGS. 9 and 14, the electromagnetic induction heater 20 comprises a coil assembly 21, the first dies 110 may be placed in the coil assembly 21, and alternating current may be set in coils in the coil assembly 21, such that the coil assembly 21 generates magnetic field perpendicular to the first bonding layers 113 to heat the first connection structures 1131.

Of course, the first connection structures 1131 may also be heated by other means. For example, the first dies 110 may be placed in the magnetic field, and the first connection structures 1131 cut the magnetic field by controlling movement of the first dies 110 within the magnetic field, such that current is generated within the first connection structures 1131 to achieve the purpose of heating the first connection structures 1131.

In some examples, each of the first metal rings 1137 of the first dies 110 are disposed as being closed around at least one of the first connection structures 1131. That is, each of the first metal rings 1137 is a complete annular structure that extends along a circumferential direction of at least one of the first connection structures 1131. Thus, after the first dies 110 are placed within the coil assembly 21 of the electromagnetic induction heater 20, the alternating magnetic field generated by the coil assembly 21 can be distributed within the first metal rings 1137 more uniformly, so as to heat the first connection structures 1131 of the first metal rings 1137 more uniformly.

Of course, each of the first metal rings 1137 of the first dies 110 may also be disposed as being not closed around at least one of first connection structures 1131. In an example, each of the first metal rings 1137 is disconnected annular structure that extends along a circumferential direction of at least one of the first connection structures 1131; alternatively, each of the first metal rings 1137 comprises a plurality of metal line segments that are sequentially distributed as spaced apart along the circumferential direction of at least one of the first connection structures 1131.

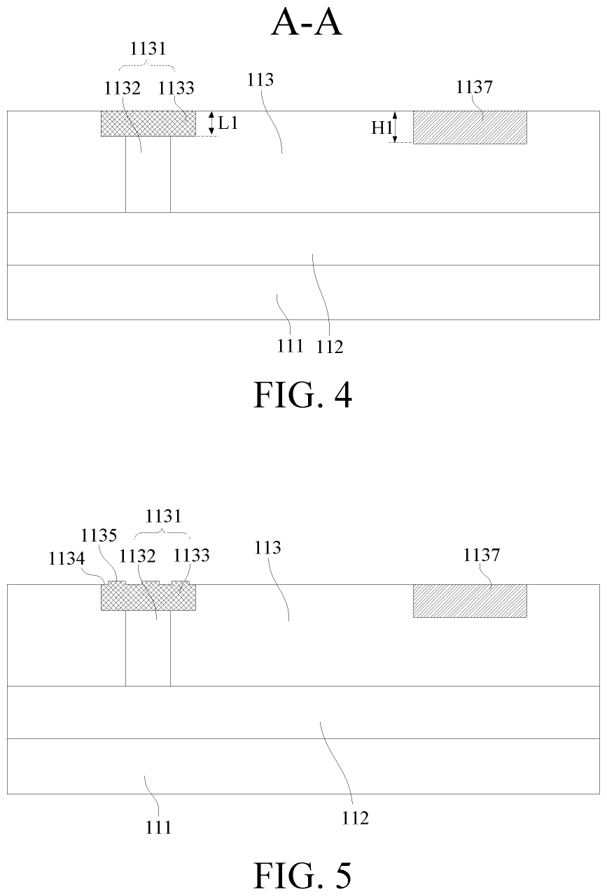

As shown in FIGS. 3 and 4, the first dies 110 comprise first substrates 111, first circuit layers 112 located on the first substrates 111, and the first bonding layers 113 located on the first circuit layers 112. Memory circuits (not shown in the figures), control circuits (not shown in the figures), etc. may be disposed within the first circuit layers 112. The first circuit layers 112 are connected with the first bonding layers 113. After the first bonding layers 113 of the first dies 110 are bonded with other dies (for example, the first bonding layers 113 of the first dies 110 are bonded with the second bonding layers 123 of the second dies 120), the first circuit layers 112 are connected with the other dies through the first bonding layers 113, so as to achieve signal transmission between the first dies 110 and the second dies 120.

The first dies 110 may be array memory chips, and may also be dies that need to be bonded with other dies. In an example, the first dies 110 are array memory chips, the first circuit layers 112 of the first dies 110 are memory array layers, each memory array layer comprises at least one memory structure, and the memory structures are connected with the first connection structures 1131 of the first bonding layers 113, so as to achieve signal transmission between the memory structures and the first connection structures 1131. The second dies 120 are peripheral circuit chips, and the first bonding layers 113 of the first dies 110 are bonded with the second dies 120, such that the first dies 110 and the second dies 120 are combined to form memory chips.

In some examples, the first connection structures 1131 of the first dies 110 each comprises a first connection line 1132 and a first connection terminal 1133, and the first connection lines 1132 are connected with the first circuit layers 112, such that signals can be transmitted between the first circuit layers 112 and the first connection lines 1132. Each of the first connection terminals 1133 is disposed at one end of each of the first connection lines 1132 far away from each of the first circuit layers 112. After the first connection terminals 1133 are heated by the electromagnetic induction heater 20, the first connection terminals 1133 may be bonded with connection terminals of other dies.

The first connection terminals 1133 are exposed to surfaces of the first bonding layers 113. The first connection structures 1131 comprises a plurality of first connection terminals 1133 and a plurality of first connection lines 1132, and the plurality of first connection lines 1132 are connected with the plurality of first connection terminals 1133 in a one-to-one correspondence manner. The plurality of first connection terminals 1133 of the first connection structures 1131 are located within the first metal rings 1137. The plurality of first connection terminals 1133 of the first connection structures 1131 are distributed in the first bonding layers 113 in an array.

As shown in FIG. 4, in a direction that is perpendicular to surfaces of sides of the first bonding layers 113 facing away from the first circuit layers 112, a thickness of the first metal rings 1137 is H1, and a thickness of the first connection terminals 1133 is L1, wherein the thickness H1 of the first metal rings 1137 may be greater than or equal to the thickness L1 of the first connection terminals 1133, such that the alternating magnetic field generated by the electromagnetic induction heater 20 can be distributed within the first metal rings 1137 more uniformly, a magnetic density (also referred to as a magnetic flux density) and a magnetic field uniformity at each of the first connection terminals 1133 within the first metal rings 1137 can be ensured, and a temperature rise of each of the first connection terminals 1133 within the first metal rings 1137 is faster and more uniform.

In addition, a ratio of the thickness HI of the first metal rings 1137 to the thickness L1 of the first connection terminals 1133 may be less than or equal to 3, so as to avoid affecting arrangement of other circuits within the first dies 110 due to the too large thickness H1 of the first metal rings 1137, or to prevent the first metal rings 1137 from occupying the space for arranging other circuits within the first dies 110.

In some examples, the thickness H1 of the first metal rings 1137 may be 1-3 times of the thickness L1 of the first connection terminals 1133, that is, the ratio of the thickness H1 of the first metal rings 1137 to the thickness LI of the first connection terminals 1133 is greater than or equal to 1 and less than or equal to 3, so as to achieve faster and more uniform temperature rise of each of the first connection terminals 1133 within the first metal rings 1137, and meanwhile, the arrangement of other circuits within the first dies 110 are not affected.

In some examples, as shown in FIG. 4, surfaces of sides of the first metal rings 1137 facing away from the first circuit layers 112 are flush with surfaces of sides of the first connection terminals 1133 facing away from the first circuit layers 112. Moreover, the thickness Hl of the first metal rings 1137 is greater than or equal to the thickness LI of the first connection terminals 1133. Then, the first connection terminals 1133 are all located within the first metal rings 1137, such that the magnetic density (also referred to as the magnetic flux density) and the magnetic field uniformity at each of the first connection terminals 1133 within the first metal rings 1137 can be ensured, thereby further improving the heating efficiency of the first connection terminals 1133.

In an example, the surfaces of the sides of the first metal rings 1137 facing away from the first circuit layers 112 are flush with the surfaces of the sides of the first connection terminals 1133 facing away from the first circuit layers 112. Moreover, the surfaces of the sides of the first metal rings 1137 facing away from the first circuit layers 112 are flush with surfaces of sides of the first bonding layers 113 facing away from the first circuit layers 112. The thickness H1 of the first metal rings 1137 is 1-3 times of the thickness L1 of the first connection terminals 1133. That is, each of the first metal rings 1137 and each of the first connection terminals 1133 are exposed to the surfaces of the first bonding layers 113, and the ratio of the thickness HI of the first metal rings 1137 to the thickness L1 of the first connection terminals 1133 is greater than or equal to 1 and less than or equal to 3.

In some examples, as shown in FIG. 11, the first connection structures 1131 further comprise first heat preservation portions 1136, and the first heat preservation portions 1136 are disposed on sidewalls of the first connection terminals 1133 to perform heat preservation on the first connection terminals 1133, such that the heat generated by the first connection terminals 1133 is concentrated on the first connection terminals 1133, the heating-up efficiency of the first connection terminals 1133 is improved. Meanwhile, the temperature of insulating materials of the first dies 110 near the first connection terminals 1133 can also be reduced, and the risk of deformation or even fracture caused by too high temperature of the insulating materials of the first dies 110 near the first connection terminals 1133 can be reduced.

Each of the first heat preservation portions 1136 may be disposed on sidewalls all around each of the first connection terminals 1133, and may also be disposed only on a sidewall of one side of each of the first connection terminals 1133. Of course, the former can further improve the heat preservation effect on the first connection terminals 1133.

As shown in FIG. 5, the first connection terminals 1133 comprise first surfaces 1134 located on sides of the first connection terminals 1133 far away from the corresponding first connection lines 1132. At least one first protrusion 1135 is disposed on each of the first surfaces 1134 convexly. When the alternating magnetic field generated by the electromagnetic induction heater 20 causes the first connection terminals 1133 to generate alternating current, the alternating current is mainly concentrated on the first protrusions 1135, such that the first protrusions 1135 have a faster temperature rise relative to other places of the first connection terminals 1133 in order to bond the first connection terminals 1133 with the connection structures of other dies through the first protrusions 1135.

In an example, a plurality of first protrusions 1135 are disposed on each of the first surfaces 1134 convexly. The plurality of first protrusions 1135 are disposed as being spaced apart from each other. The first protrusions 1135 may be pillar-shaped structures that protrude out from the first surfaces 1134, or prismatic structures that protrude out from the first surfaces 1134 and extend along the first surfaces 1134.

In some examples, as shown in FIGS. 3, 6 and 8, the semiconductor device 10 further comprises second dies 120 corresponding to the first dies 110, wherein the second dies 120 comprise second bonding layers 123. The second bonding layers 123 of the second dies 120 are configured to bond with the first bonding layers 113 of the first dies 110, so as to achieve signal transmission between the first dies 110 and the second dies 120.

The second bonding layers 123 comprise second connection structures 1231 and second metal rings 1237, and each of the second metal rings 1237 is disposed around at least one of the second connection structures 1231. The second connection structures 1231 are configured to bond with the first connection structures 1131 of the first dies 110.

In the semiconductor device 10 provided by examples of the present application, the first bonding layers 113 of the first dies 110 are provided with the first metal rings 1137 each surrounding at least one of the first connection structures 1131, and the second bonding layers 123 of the second dies 120 are provided with the second metal rings 1237 each surrounding at least one of the second connection structures 1231. The first bonding layers 113 of the first dies 110 and the second bonding layers 123 of the second dies 120 may be disposed in face-to-face manner and then placed in the alternating magnetic field, the current is generated in the first connection structures 1131 within the first dies 110 and in the second connection structure 1231 within the second dies 120 through the alternating magnetic field, such that the first connection structures 1131 and the second connection structure 1231 are heated, thereby connecting the first connection structures 1131 of the first dies 110 with the second connection structure 1231 of the second dies 120 by bonding. However, the insulating materials of the first dies 110 and the second dies 120 do not generate current in the alternating magnetic field and are not heated. Therefore, the insulating materials of the first dies 110 and the second dies 120 can maintain a low temperature to reduce the risk of deformation or even fracture caused by stress generated due to a high temperature inside the first dies 110 and the second dies 120 of the semiconductor device 10.

Moreover, by disposing the second metal rings 1237, the alternating magnetic fields can be uniformly distributed within the second metal rings 1237, so as to heat the second connection structures 1231 more uniformly, and temperature distribution of the second connection structures 1231 is more uniform, such that the second connection structures 1231 of the second dies 120 are fully connected with the connection structures of other dies by bonding.

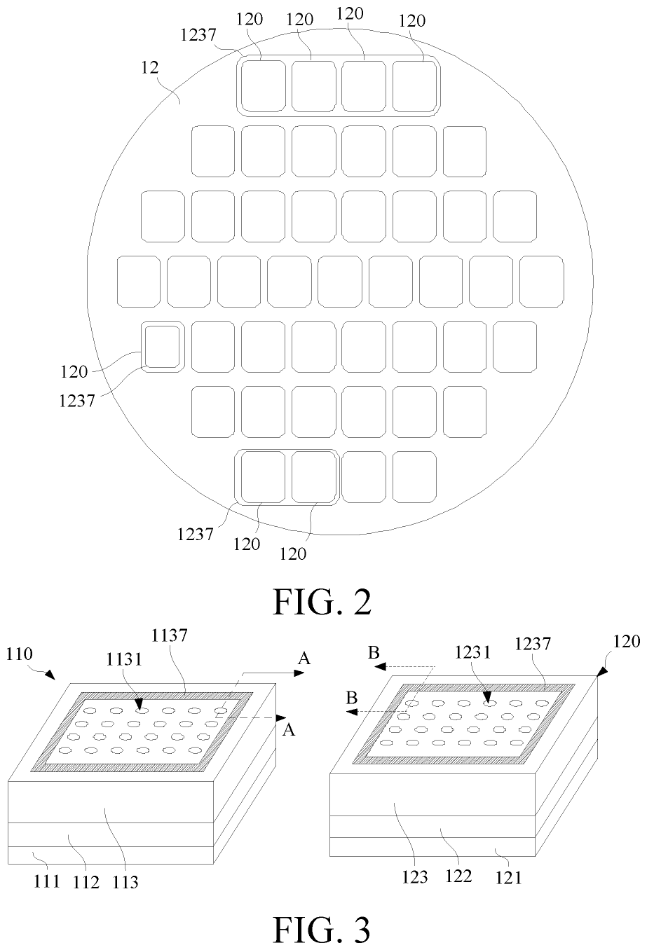

It is to be noted that, each of the second metal rings 1237 may be disposed around the second connection structure 1231 of one of the second dies 120, or disposed around the second connection structures 1231 of a plurality of the second dies 120. In an example, as shown in FIG. 2, a second wafer 12 comprises a plurality of second dies 120, such that each of the second metal rings 1237 may be disposed around the second connection structure 1231 of one of the second dies 120, or each of the second metal rings 1237 may be disposed around the second connection structures 1231 of two, three, four or more of the second dies 120.

In addition, the electromagnetic induction heater 20 may generate alternating magnetic field (also referred to as alternating electromagnetic field or time-varying electromagnetic field) that is perpendicular to the second bonding layers 123 of the second dies 120, such that alternating current is generated within the second connection structures 1231, thereby heating the second connection structures 1231.

In an example, as shown in FIG. 9, the second dies 120 may be placed in the coil assembly 21, and the alternating current may be set in coils in the coil assembly 21, such that the coil assembly 21 generates magnetic field perpendicular to the second bonding layers 123 to heat the second metal rings 1237.

Of course, the second metal rings 1237 may also be heated by other means. For example, the second dies 120 may be placed in the magnetic field, and the second metal rings 1237 cut the magnetic field by controlling movement of the second dies 120 within the magnetic field, such that the current is generated within the second metal rings 1237, so as to achieve the purpose of heating the second metal rings 1237.

In some examples, each of the second metal rings 1237 of the second dies 120 is disposed as being closed around at least one of the second connection structures 1231. That is, each of the second metal rings 1237 is a complete annular structure that extends along a circumferential direction of at least one of the second connection structures 1231. After the second dies 120 are placed in the coil assembly 21 of the electromagnetic induction heater 20, the alternating magnetic field generated by the coil assembly 21 can be distributed within the second metal rings 1237 more uniformly, so as to heat the second connection structures 1231 of the second metal rings 1237 more uniformly.

Of course, each of the second metal rings 1237 of the second dies 120 may also be disposed as being not closed around at least one of second connection structures 1231. In an example, each of the second metal rings 1237 is a disconnected annular structure that extends along a circumferential direction of at least one of the second connection structures 1231; alternatively, each of the second metal rings 1237 comprises a plurality of metal line segments that are sequentially distributed as being spaced apart along the circumferential direction of at least one of the second connection structures 1231.

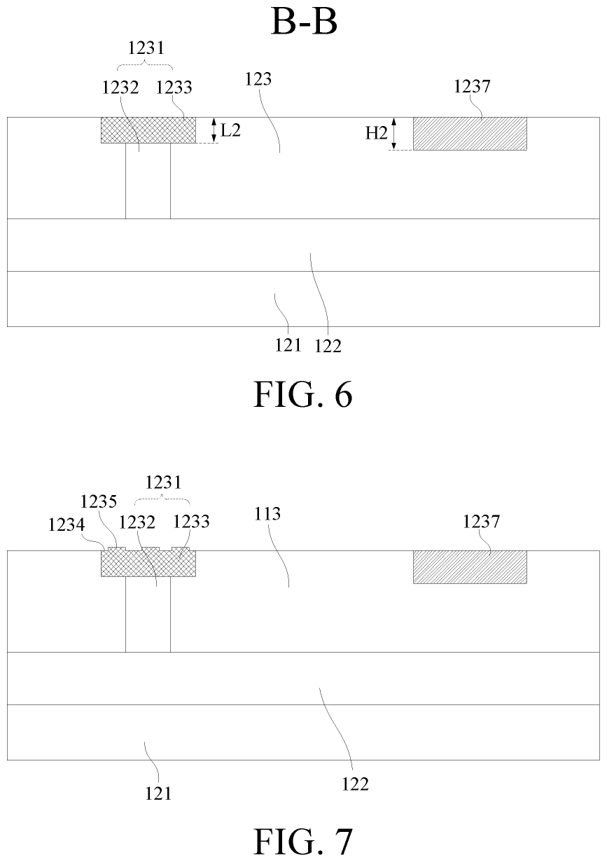

As shown in FIGS. 3 and 6, the second dies 120 comprise second substrates 121, second circuit layers 122 located on sides of the second substrates 121 close to the first dies 110, and the second bonding layers 123 located on sides of the second circuit layers 122 close to the first dies 110. Control circuits or other circuits may be disposed within the second circuit layers 122. The second circuit layers 122 are connected with the second bonding layers 123. After the second bonding layers 123 of the second dies 120 are bonded with other dies (for example, the second bonding layers 123 of the second dies 120 are bonded with the first bonding layers 113 of the first dies 110), the second circuit layers 122 are connected with the other dies through the second bonding layers 123, so as to achieve signal transmission between the second dies 120 and the other dies.

The second dies 120 may be peripheral circuit chips, and may also be dies that need to be bonded with the other dies. When the second dies 120 are peripheral circuit chips, the manner of bonding the second dies 120 with the first dies 110 to form memory chips may refer to the above description, which is not repeated here.

In some examples, the second connection structures 1231 each comprises a second connection line 1232 and a second connection terminal 1233, wherein the second connection lines 1232 are connected with the second circuit layers 122, such that signals can be transmitted between the second circuit layers 122 and the second connection lines 1232. The second connection terminals 1233 are disposed at ends of the second connection lines 1232 far away from the second circuit layers 122. After the second connection terminals 1233 are heated by the electromagnetic induction heater 20, the second connection terminals 1233 may be stably bonded with connection terminals of the other dies.

The second connection terminals 1233 are exposed to surfaces of the second bonding layers 123. The second connection structures 1231 comprises a plurality of second connection terminals 1233 and a plurality of second connection lines 1232, wherein the plurality of second connection lines 1232 are connected with the plurality of second connection terminals 1233 in a one-to-one correspondence manner. The plurality of second connection terminals 1233 of the second connection structures 1231 are located within the second metal rings 1237. The plurality of second connection terminals 1233 of the second connection structures 1231 are distributed in the second bonding layers 123 in an array.

As shown in FIG. 6, in a direction that is perpendicular to surfaces of sides of the second bonding layers 123 facing away from the second circuit layers 122, a thickness of the second metal rings 1237 is H2, and a thickness of the second connection terminals 1233 are L2. The thickness H2 of the second metal rings 1237 may be greater than or equal to the thickness L2 of the second connection terminals 1233, such that the alternating magnetic field generated by the electromagnetic induction heater 20 can be distributed within the second metal rings 1237 more uniformly, the magnetic density (also referred to as the magnetic flux density) and the magnetic field uniformity at each of the second connection terminals 1233 within the second metal rings 1237 can be ensured, and a temperature rise of each of the second connection terminals 1233 within the second metal rings 1237 is faster and more uniform.

In addition, a ratio of the thickness H2 of the second metal rings 1237 to the thickness L2of the second connection terminals 1233 may be less than or equal to 3, so as to avoid affecting arrangement of other circuits within the second dies 120 due to the too large thickness H2 of the second metal rings 1237, or to prevent the second metal rings 1237 from occupying the space for arranging other circuits within the second dies 120.

In some examples, the thickness H2 of the second metal rings 1237 may be 1-3 times of the thickness L2 of the second connection terminals 1233, that is, the ratio of the thickness H2 of the second metal rings 1237 to the thickness L2 of the second connection terminals 1233 is greater than or equal to 1 and less than or equal to 3, so as to achieve faster and more uniform temperature rise of the second connection terminals 1233 within the second metal rings 1237, and meanwhile, the arrangement of other circuits within the second dies 120 are not affected.

In some examples, as shown in FIG. 6, surfaces of sides of the second metal rings 1237 facing away from the second circuit layers 122 are flush with surfaces of sides of the second connection terminals 1233 facing away from the second circuit layers 122. Moreover, the thickness H2 of the second metal rings 1237 is greater than or equal to the thickness L2 of the second connection terminals 1233. Then, the second connection terminals 1233 are all located within the second metal rings 1237, such that the magnetic density (also referred to as the magnetic flux density) and the magnetic field uniformity at each of the second connection terminals 1233 within the second metal rings 1237 can be ensured, thereby further improving the heating efficiency of the second connection terminals 1233.

In an example, the surfaces of the sides of the second metal rings 1237 facing away from the second circuit layers 122 are flush with the surfaces of the sides of the second connection terminals 1233 facing away from the second circuit layers 122. Moreover, the surfaces of the sides of the second metal rings 1237 facing away from the second circuit layers 122 are flush with surfaces of sides of the second bonding layers 123 far away from the second circuit layers 122. The thickness H2 of the second metal rings 1237 is 1-3 times of the thickness L2 of the second connection terminals 1233. That is, each of the second metal rings 1237 and each of the second connection terminals 1233 are exposed to the surfaces of the second bonding layers 123, and the ratio of the thickness H2 of the second metal rings 1237 to the thickness L2 of the second connection terminals 1233 is greater than or equal to 1 and less than or equal to 3.

In some examples, as shown in FIG. 11, the second connection structures 1231 further comprise second heat preservation portions 1236, and the second heat preservation portions 1236 are disposed on sidewalls of the second connection terminals 1233 to perform heat preservation on the second connection terminals 1233, such that the heat generated by the second connection terminals 1233 is concentrated on the second connection terminals 1233, the heating-up efficiency of the second connection terminals 1233 is improved. Meanwhile, the temperature of insulating materials of the second dies 120 near the second connection terminals 1233 can also be reduced, and the risk of deformation or even fracture caused by too high temperature of the insulating materials of the second dies 120 near the second connection terminals 1233 can be reduced.

Each of the second heat preservation portions 1236 may be disposed on sidewalls all around each of the second connection terminals 1233, and may also be disposed only on a sidewall of one side of each of the second connection terminals 1233. Of course, the former can further improve the heat preservation effect on the second connection terminals 1233.

As shown in FIG. 7, the second connection terminals 1233 comprise second surfaces 1234 located on sides of the second connection terminals 1233 far away from the corresponding second connection lines 1232. In some examples, at least one second protrusion 1235 is disposed on each of the second surfaces 1234 convexly. When the alternating magnetic field generated by the electromagnetic induction heater 20 causes the second connection terminals 1233 to generate the alternating current, the alternating current is mainly concentrated on the second protrusions 1235, such that the second protrusions 1235 have a faster temperature rise relative to other places of the second connection terminals 1233 in order to bond the second connection terminals 1233 with the connection structures of other dies through the second protrusions 1235.

In an example, a plurality of second protrusions 1235 are disposed on each of the second surfaces 1234 convexly. The plurality of second protrusions 1235 are disposed as being spaced apart from each other. The second protrusions 1235 may be pillar-shaped structures that protrude out from the second surfaces 1234, or prismatic structures that protrude out from the second surfaces 1234 and extend along the second surfaces 1234.

In some examples, orthographic projections of the first metal rings 1137 of the first dies 110 on the second dies 120 at least partially overlap with the second metal rings 1237. Thus, when the first dies 110 and the second dies 120 are bonded together, the first metal rings 1137 and the second metal rings 1237 are connected with each other, so as to improve the bonding strength and reliability between the first dies 110 and the second dies 120.

The orthographic projections of the first metal rings 1137 of the first dies 110 on the second dies 120 may partially overlap with the second metal rings 1237 of the second dies 120 and may also completely overlap with the second metal rings 1237 of the second dies 120. Of course, the latter can further improve the connection strength between the first metal rings 1137 and the second metal rings 1237, thereby further improving the bonding strength and reliability between the first dies 110 and the second dies 120.

Examples of the present application further provide a semiconductor apparatus, which is configured to perform electromagnetic heating on a semiconductor device in a bonding process. As shown in FIGS. 9 and 14, the semiconductor apparatus 1 comprises an electromagnetic induction heater 20 configured to surround a semiconductor device 10 in the bonding process, and the semiconductor device 10 is the semiconductor device 10 of any of the above examples.

The electromagnetic induction heater 20 comprises a coil assembly 21, alternating current is set within coils in the coil assembly 21, and the coil assembly 21 generates magnetic field perpendicular to the first bonding layers 113, so as to form uniformly distributed alternating magnetic field within the first metal rings 1137, such that the first connection structures 1131 are uniformly heated. When the second dies 120 comprise the second metal rings 1237, the electromagnetic induction heater 20 may also form uniformly distributed alternating magnetic field within the second metal rings 1237, such that the second connection structures 1231 are uniformly heated to bond the first bonding layers 113 of the first dies 110 with the second bonding layers 123 of the second dies 120.

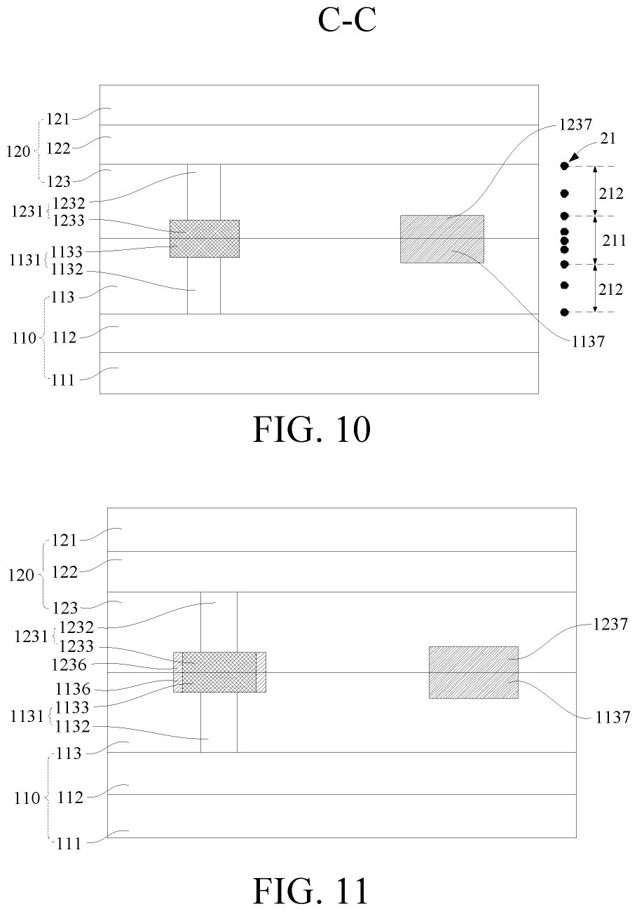

As shown in FIG. 10, the coil assembly 21 of the electromagnetic induction heater 20 comprises a first winding area 211 and second winding areas 212 located on two sides of the first winding area 211. The first winding area 211 corresponds to a position of a junction of the first bonding layers 113 and the second bonding layers 123, and a coil density within the first winding area 211 is greater than a coil density within the second winding areas 212.

After the semiconductor device 10 is placed within the coil assembly 21, the first winding area 211 may correspond to the position of the junction of the first bonding layers 113 and the second bonding layers 123. After the coil assembly 21 generates the magnetic field perpendicular to the first bonding layers 113, the magnetic density (also referred to as the magnetic flux density) close to the junction of the first bonding layers 113 and the second bonding layers 123 is greater, such that the current generated by the first connection terminals 1133 of the first connection structures 1131 and the second connection terminals 1233 of the second connection structures 1231 is greater, and the temperature is higher, thereby better bonding the first bonding layers 113 and the second bonding layers 123 together at the junction.

On the other hand, the magnetic density (also referred to as the magnetic flux density) within the first dies 110 and the second dies 120 far away from the junction of the first bonding layers 113 and the second bonding layers 123 is smaller, the current generated by metal portions within the first dies 110 and the second dies 120 far away from the junction of the first bonding layers 113 and the second bonding layers 123 is also relatively smaller, and the temperature is lower, thereby reducing the risk of deformation or even fracture of the portions of the first dies 110 and the second dies 120 far away from the junction of the first bonding layers 113 and the second bonding layers 123 due to the high temperature.

It is to be noted that, the coil density within the first winding area 211 being greater than the coil density within the second winding areas 212 means that: in a direction that is perpendicular to surfaces of sides of the first bonding layers 113 facing away from the first circuit layers 112, the number of turns of a coil in a unit length of the first winding area 211 is greater than the number of turns of a coil in a unit length of the second winding areas 212. The coil density within the two second winding areas 212 may be the same, or may also be different, which is not limited here. In addition, in the direction that is perpendicular to the surfaces of the sides of the first bonding layers 113 facing away from the first circuit layers 112, the length of the first winding area 211 and the lengths of the second winding areas 212 may be the same, or may also be different, which is not limited here.

As shown in FIG. 14, the electromagnetic induction heater 20 further comprises a base 22 that is connected with the coil assembly 21, so as to provide alternating current to the coil assembly 21 to cause the coil assembly 21 to generate alternating magnetic field.

To better fabricate the semiconductor device in the examples of the present application, the examples of the present application further provide a fabrication method of a semiconductor device. As shown in FIG. 15, the method mainly comprises operation S110 to operation S130 which are detailed as follows:

S110, first dies and second dies are provided, the first dies comprise first bonding layers, first connection structures and first metal rings, each of the first metal rings is disposed as being closed around at least one of the first connection structures, and the second dies comprise second bonding layers and second connection structures.

As shown in FIGS. 1 and 10, the first bonding layers 113 of the first dies 110 are configured to bond with the second bonding layers 123 of the second dies 120, such that the first connection structures 1131 of the first dies 110 are connected with the second connection structures 1231 of the second dies 120, so as to achieve signal transmission between the first dies 110 and the second dies 120. Each of the first metal rings 1137 may be disposed as being closed around one of the first connection structures 1131, or may also be disposed as being closed around two, three, four or more of the first connection structures 1131.

S120, the first bonding layers and the second bonding layers are disposed in face-to-face manner, with the first connection structures and the second connection structures being disposed in a contraposition contact manner.

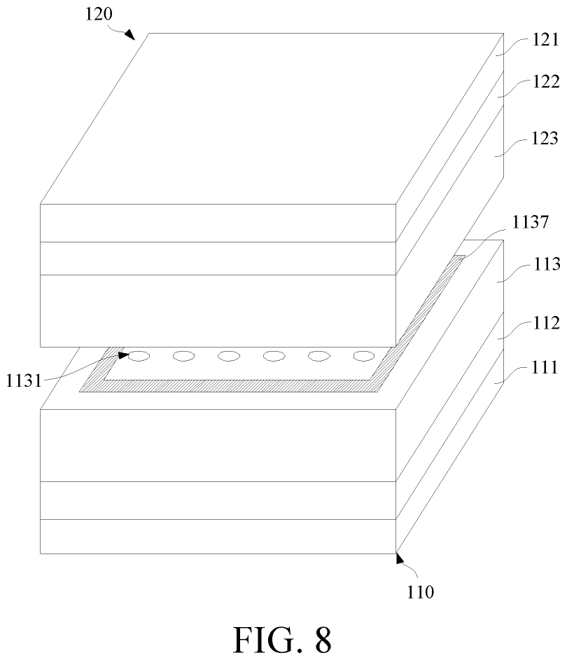

As shown in FIGS. 8 and 10, by disposing the first bonding layers 113 and the second bonding layers 123 in face-to-face manner and disposing the first connection structures 1131 and the second connection structures 1231 in a contraposition contact manner, after the first bonding layers 113 are bonded with the second bonding layers 123, the first connection structures 1131 and the second connection structures 1231 are connected together by bonding, so as to achieve signal transmission between the first connection structures 1131 and the second connection structures 1231.

S130, the first connection structures are connected with the second connection structures by bonding.

In the fabrication method of the semiconductor device provided by the examples of the present application, the first bonding layers 113 of the first dies 110 is provided with the first metal rings 1137 each surrounding at least one of the first connection structures 1131. Thus, the first dies 110 may be placed in the alternating magnetic field, the current is generated within the first connection structures 1131 in the first dies 110 through the alternating magnetic field to heat the first connection structures 1131, such that the first connection structures 1131 of the first dies 110 are bonded with connection structures of other dies. However, insulating materials of the first dies 110 do not generate current in the alternating magnetic field and are not heated. Therefore, the insulating materials of the first dies 110 can maintain a lower temperature to reduce the risk of deformation or even fracture caused by stress generated due to a high temperature inside the first dies 110 of the semiconductor device 10.

That is, the semiconductor device 10 provided by examples of the present application can achieve heating of the first connection structures 1131 of the first dies 110 to a high temperature, such that the first connection structures 1131 of the first dies 110 can have high bonding strength and reliability with the connection structures of the other dies after bonding. Meanwhile, regions formed by the insulating materials in the first dies 110 can maintain a low temperature to reduce the risk of deformation or even fracture caused by the stress generated due to the high temperature inside the first dies 110.

Moreover, by disposing the first metal rings 1137 as being closed, the alternating magnetic field can be uniformly distributed within the first metal rings 1137, so as to heat the first connection structures 1131 more uniformly, and temperature distribution of the first connection structures 1131 is more uniform, such that the first connection structures 1131 of the first dies 110 are fully connected with the connection structures of other dies by bonding, thereby further improving the bonding strength and reliability of the first dies 110 and other dies.

Connecting the first connection structures with the second connection structures by bonding comprises: disposing an electromagnetic induction heater 20 at peripheries of the first bonding layers 113 and the second bonding layers 123; starting the electromagnetic induction heater 20 to connect the first connection structures 1131 with the second connection structures 1231 by bonding.

Heating the first connection structures 1131 outside the semiconductor device 10 can be achieved by the electromagnetic induction heater 20. The electromagnetic induction heater 20 may generate alternating magnetic field (also referred to as alternating electromagnetic field or time-varying electromagnetic field) that is perpendicular to the first bonding layers 113 of the first dies 110, such that alternating current is generated within the first connection structures 1131, thereby heating the first connection structures 1131. A structure of the electromagnetic induction heater 20 may refer to the above description, which is no longer repeated here.

Of course, the fabrication method of the semiconductor device provided by the examples of the present application may also heat the first connection structures 1131 by other means. For example, the first dies 110 may be placed in the magnetic field, and the first connection structures 1131 cut the magnetic field by controlling movement of the first dies 110 within the magnetic field, such that current is generated within the first connection structures 1131, so as to achieve the purpose of heating the first connection structures 1131.

In the above operation of providing the first dies and the second dies, as shown in FIG. 3, the first connection structures 1131 are exposed to the surfaces of the first bonding layers 113, and the first metal rings 1137 are exposed to surfaces of the first bonding layers 113. The second connection structures 1231 are exposed to surfaces of the second bonding layers 123. In an example, the first connection terminals 1133 of the first connection structures 1131 are exposed to surfaces of sides of the first bonding layers 113 facing away from the first circuit layers 112. The first metal rings 1137 are exposed to the surfaces of the sides of the first bonding layers 113 facing away from the first circuit layers 112. The second connection terminals 1233 of the second connection structures 1231 are exposed to surfaces of sides of the second bonding layers 123 facing away from the second circuit layers 122.

By exposing the first connection structures 1131 to the surfaces of the first bonding layers 113 and exposing the second connection structures 1231 to the surfaces of the second bonding layers 123, after the first bonding layers 113 and the second bonding layers 123 are disposed in face-to-face manner, the first connection structures 1131 and the second connection structures 1231 can be disposed in a contraposition contact manner, such that the first connection structures 1131 and the second connection structures 1231 are connected by bonding after heating.

In addition, by exposing the first metal rings 1137 to the surfaces of the first bonding layers 113, the first metal rings 1137 are close to a junction of the first bonding layers 113 and the second bonding layers 123, such that a magnetic density within the first metal rings 1137 close to the junction of the first bonding layers 113 and the second bonding layers 123 is highest, so as to further improve the heating efficiency of portions of the first connection structures 1131 close to the junction of the first bonding layers 113 and the second bonding layers 123.

In some examples, in the above operation of providing the first dies and the second dies, as shown in FIGS. 2 and 3, the second dies 120 further comprise second metal rings 1237 that are exposed to the surfaces of the second bonding layers 123, and each of the second metal rings 1237 is disposed as being closed around at least one of the second connection structures 1231.

By causing the second dies 120 to comprise the second metal rings 1237 each being disposed as being closed around at least one of the second connection structures 1231, the second connection structures 1231 within the second metal rings 1237 can be uniformly heated by the electromagnetic induction heater 20, so as to stably connect the second connection structures 1231 with the first connection structures 1131 by bonding. Each of the second metal rings 1237 may be disposed as being closed around one of the second connection structures 1231, or may also disposed as being closed around a plurality of the second connection structures 1231.

Moreover, by exposing the second metal rings 1237 to the surfaces of the second bonding layers 123, the second metal rings 1237 are close to the junction of the first bonding layers 113 and the second bonding layers 123, such that the magnetic density within the second metal rings 1237 close to the junction of the first bonding layers 113 and the second bonding layers 123 is highest, so as to further improve the heating efficiency of portions of the second connection structures 1231 close to the junction of the first bonding layers 113 and the second bonding layers 123.

With continued reference to FIG. 3, the first metal rings 1137 are exposed to the surfaces of the first bonding layers 113, and the second metal rings 1237 are exposed to the surfaces of the second bonding layers 123, such that the first metal rings 1137 can be connected with the second metal rings 1237 by bonding, so as to further improve the bonding strength and reliability of the first dies 110 and the second dies 120.

In some examples, providing the first dies and the second dies comprises: providing a first wafer comprising a plurality of first dies. The first metal rings are disposed around the plurality of first dies. In an example, as shown in FIG. 1, the plurality of first dies 110 on the first wafer 11 are distributed in an array. The first metal rings 1137 may be disposed around the plurality of consecutive first dies 110 that are located in the same row or the same column.

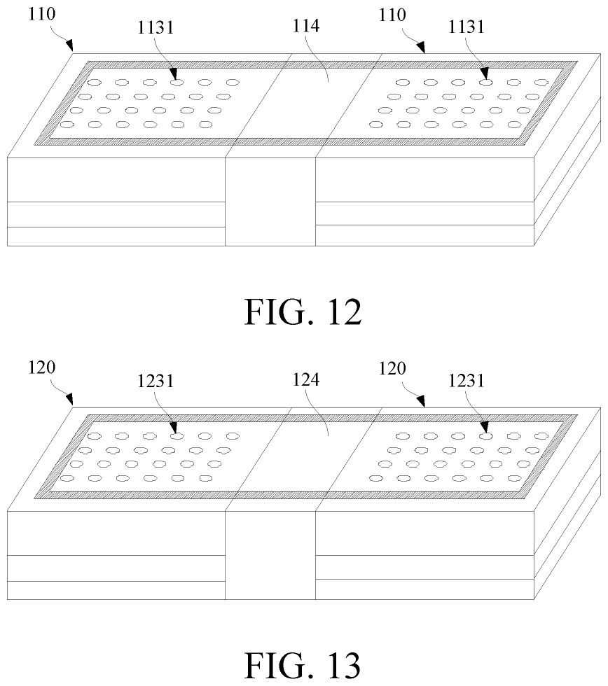

Providing the first wafer comprises: providing the first wafer, wherein the first wafer comprises a first dielectric layer, the first dielectric layer connects the first bonding layers of the plurality of first dies, and the first metal rings are disposed in the first dielectric layer and the first bonding layers. As shown in FIGS. 1 and 12, by disposing the first metal rings 1137 in the first dielectric layer 114 and the first bonding layers 113, disposing the first metal rings 1137 around the plurality of first dies 110 can be achieved.

In some examples, providing the first dies and the second dies comprises: providing a second wafer comprising a plurality of second dies. The second metal rings are disposed around the plurality of second dies. In an example, as shown in FIG. 2, the plurality of second dies 120 on the second wafer 12 are distributed in an array. The second metal rings 1237 may be disposed around the plurality of consecutive second dies 120 that are located in the same row or the same column.

Providing the second wafer comprises: providing the second wafer, wherein the second wafer comprises a second dielectric layer, the second dielectric layer connects the second bonding layers of the plurality of second dies, and the second metal rings are disposed in the second dielectric layer and the second bonding layers. As shown in FIGS. 2 and 13, by disposing the second metal rings 1237 in the second dielectric layer 124 and the second bonding layers 123, disposing the second metal rings 1237 around the plurality of second dies 120 can be achieved.

In some examples, in the operation of disposing the first bonding layers and the second bonding layers in face-to-face manner, with the first connection structures and the second connection structures being disposed in a contraposition contact manner, as shown in FIGS. 8 and 10, orthographic projections of the first metal rings 1137 on the second dies 120 at least partially overlap with the second metal rings 1237. Thus, when the first dies 110 and the second dies 120 are bonded together, the first metal rings 1137 and the second metal rings 1237 are connected with each other, so as to improve the bonding strength and reliability between the first dies 110 and the second dies 120.

The orthographic projections of the first metal rings 1137 of the first dies 110 on the second dies 120 may partially overlap with the second metal rings 1237 of the second dies 120, or may also completely overlap with the second metal rings 1237 of the second dies 120. Of course, the latter can further improve the connection strength between the first metal rings 1137 and the second metal rings 1237, thereby further improving the bonding strength and reliability between the first dies 110 and the second dies 120.

In some examples, disposing the first bonding layers and the second bonding layers in face-to-face manner, with the first connection structures and the second connection structures being disposed in a contraposition contact manner, may comprise: disposing the first wafer and the second wafer in face-to-face manner, such that the first bonding layers of the plurality of first dies of the first wafer and the second bonding layers of the plurality of second dies of the second wafer are disposed in a one-to-one face-to-face manner, and the first connection structures of the plurality of first bonding layers and the second connection structures of the plurality of second bonding layers are disposed in a one-to-one contraposition contact manner.

Thus, the first wafer 11 and the second wafer 12 may be directly placed in the coil assembly 21 of the electromagnetic induction heater 20, and the first connection structures 1131 of the plurality of first dies 110 may be simultaneously heated by the coil assembly 21, such that the plurality of first dies 110 are connected with the plurality of second dies 120 by bonding.

The present application provides semiconductor devices, fabrication methods of semiconductor devices, and semiconductor apparatus, so as to solve problems including that the semiconductor device is prone to deformation or even fracture.

Examples of the present application provide a semiconductor device, comprising: first dies comprising first bonding layers, wherein the first bonding layers comprise first connection structures and first metal rings, each of the first metal rings is disposed around at least one of the first connection structures.

In some examples, each of the first metal rings is disposed as being closed around at least one of the first connection structure.

In some examples, the first dies comprise first substrates, first circuit layers located on the first substrates, and the first bonding layers located on the first circuit layers; the first connection structures comprise first connection lines and first connection terminals, the first connection lines are connected with the first circuit layers, the first connection terminals are disposed at ends of the first connection lines far away from the first circuit layers.

In some examples, in a direction perpendicular to the first bonding layers, a thickness of the first metal rings is 1-3 times of a thickness of the first connection terminals.

In some examples, the first connection structures further comprise first heat preservation portions that are disposed on sidewalls of the first connection terminals.

In some examples, the semiconductor device further comprises second dies corresponding to the first dies, the second dies comprise second bonding layers, wherein the second bonding layers comprise second connection structures and second metal rings, each of the second metal rings is disposed around at least one of the second connection structures.

In some examples, each of the second metal rings is disposed as being closed around at least one of the second connection structures.

In some examples, orthographic projections of the first metal rings on the second dies at least partially overlap with the second metal rings.

In some examples, the second dies comprise second substrates, second circuit layers located on sides of the second substrates close to the first dies, and the second bonding layers located on sides of the second circuit layers close to the first dies; the second connection structures comprise second connection lines and second connection terminals, the second connection lines are connected with the second circuit layers, the second connection terminals are disposed at ends of the second connection lines far away from the second circuit layers.

In some examples, a thickness of the second metal rings is 1-3 times of a thickness of the second connection terminals.

In some examples, the second connection structures further comprise second heat preservation portions that are disposed on sidewalls of the second connection terminals.

Examples of the present application provide a fabrication method of a semiconductor device, comprising: providing first dies and second dies, wherein the first dies comprise first bonding layers, first connection structures and first metal rings, each of the first metal rings is disposed as being closed around at least one of the first connection structures, the second dies comprise second bonding layers and second connection structures; disposing the first bonding layers and the second bonding layers in face-to-face manner, with the first connection structures and the second connection structures being disposed in a contraposition contact manner; and connecting the first connection structures with the second connection structures by bonding.

In some examples, in providing the first dies and the second dies, the first connection structures are exposed to surfaces of the first bonding layers, the first metal rings are exposed to the surfaces of the first bonding layers, the second connection structures are exposed to surfaces of the second bonding layers.

In some examples, connecting the first connection structures with the second connection structures by bonding comprises: disposing an electromagnetic induction heater at peripheries of the first bonding layers and the second bonding layers; and starting the electromagnetic induction heater to connect the first connection structures with the second connection structures by bonding.

In some examples, the electromagnetic induction heater comprises a coil assembly, alternating current is set within coils in the coil assembly, the coil assembly generates magnetic field perpendicular to the first bonding layers.

In some examples, the coil assembly comprises a first winding area and second winding areas located on two sides of the first winding area, wherein the first winding area corresponds to the first bonding layers, a coil density within the first winding area is greater than a coil density within the second winding areas.

In some examples, providing the first dies and the second dies comprises: providing a first wafer comprising a plurality of the first dies, wherein the first metal rings are disposed around the plurality of the first dies.

In some examples, providing the first wafer comprises: providing the first wafer, the first wafer comprising a first dielectric layer, the first dielectric layer connecting the first bonding layers of the plurality of the first dies, wherein the first metal rings are disposed in the first dielectric layer and the first bonding layers.

In some examples, in providing the first dies and the second dies, the second dies further comprise second metal rings that are exposed to surfaces of the second bonding layers, each of the second metal rings is disposed as being closed around at least one of the second connection structures.

In some examples, providing the first dies and the second dies comprises: providing a second wafer comprising a plurality of the second dies, wherein the second metal rings are disposed around the plurality of the second dies.

In some examples, providing the second wafer comprises: providing the second wafer, the second wafer comprising a second dielectric layer, the second dielectric layer connecting the second bonding layers of the plurality of the second dies, wherein the second metal rings are disposed in the second dielectric layer and the second bonding layers.

In some examples, in disposing the first bonding layers and the second bonding layers in face-to-face manner, with the first connection structures and the second connection structures being disposed in a contraposition contact manner, orthographic projections of the first metal rings on the second dies at least partially overlap with the second metal rings.

Examples of the present application provide a semiconductor apparatus, which comprises an electromagnetic induction heater configured to surround a semiconductor device in a bonding process, the semiconductor device is the semiconductor device as described above. The semiconductor device comprises first dies that comprise first bonding layers, wherein the first bonding layers comprise first connection structures and first metal rings, each of the first metal rings is disposed around at least one of the first connection structures.

In the semiconductor device provided by examples of the present application, by disposing the first metal rings each surrounding at least one of the first connection structures on the first bonding layers of the first dies, the first dies may be placed in alternating magnetic field, and current is generated within the first connection structures in the first dies through the alternating magnetic field, such that the first connection structures are heated, thereby bonding the first connection structures of the first dies to the connection structures of other dies. However, insulating materials of the first dies do not generate current in the alternating magnetic field and are not heated. Therefore, the insulating materials of the first dies can maintain a low temperature to reduce the risk of deformation or even fracture caused by stress generated due to high temperature inside the first dies of the semiconductor device.

Moreover, by disposing the first metal rings, the alternating magnetic field can be uniformly distributed within the first metal rings to heat the first connection structures more uniformly, such that temperature distribution of the first connection structures is more uniform, in order that the first connection structures of the first dies are fully connected with the connection structures of the other dies by bonding.

A semiconductor device, a fabrication method of the semiconductor device and a semiconductor apparatus provided by the examples of the present application are introduced above in detail. The principle and examples of the present application are set forth herein by applying specific individual cases. The descriptions of the above examples are only used to help understand the methods and core ideas of the present application. Meanwhile, those having ordinary skill in the art may make changes over the specific implementation and application scope according to the ideas of the present application. To sum up, the contents of this specification should not be interpreted as limitations to the present application.

What is claimed is:

1. A semiconductor device, comprising:
a first die comprising a first bonding layer and
a first metal ring, wherein the first bonding layer includes a first connection structure and the first metal ring is disposed around the first connection structure.

2. The semiconductor device of claim 1, wherein the first metal ring is closed around the first connection structure.

3. The semiconductor device of claim 1, wherein the first die includes a first substrate, a first circuit layer located on the first substrate, and the first bonding layer located on the first circuit layer; and
the first connection structure includes a first connection line and a first connection terminal, the first connection line is connected with the first circuit layer, the first connection terminal is disposed at an end of the first connection line far away from the first circuit layer.

4. The semiconductor device of claim 3, wherein in a direction perpendicular to the first bonding layer, a thickness of the first metal ring is 1-3 times of a thickness of the first connection terminal.

5. The semiconductor device of claim 3, wherein the first connection structure further includes a first heat preservation portion that is disposed on a sidewall of the first connection terminal.

6. The semiconductor device of claim 1, further includes a second die corresponding to the first die, the second die including a second bonding layer,
wherein the second bonding layer includes a second connection structure and a second metal ring disposed around the second connection structure.

7. The semiconductor device of claim 6, wherein the second metal ring is closed around the second connection structure and an orthographic projection of the first metal ring on the second die at least partially overlaps with the second metal ring.

8. The semiconductor device of claim 6, wherein the second die includes a second substrate, a second circuit layer located on a side of the second substrate close to the first die, and the second bonding layer is located on a side of the second circuit layer close to the first die; and
the second connection structure includes a second connection line and a second connection terminal, the second connection line is connected with the second circuit layer, the second connection terminal is disposed at an end of the second connection line far away from the second circuit layer.

9. The semiconductor device of claim 8, wherein a thickness of the second metal ring is 1-3 times of a thickness of the second connection terminal.

10. The semiconductor device of claim 8, wherein the second connection structure further includes a second heat preservation portion that is disposed on a sidewall of the second connection terminal.

11. A fabrication method of a semiconductor device, comprising:
providing a first die and a second die, wherein the first die comprises a first bonding layer, a first connection structure and a first metal ring, the first metal ring closed around the first connection structure, the second die including a second bonding layer and a second connection structure;
disposing the first bonding layer and the second bonding layer in face-to-face manner, the first connection structure and the second connection structure being disposed in a contraposition contact manner; and
connecting the first connection structure with the second connection structure by bonding.

12. The fabrication method of the semiconductor device of claim 11, wherein in providing the first die and the second die, the first connection structure is exposed to a surface of the first bonding layer, the first metal ring is exposed to the surfaces of the first bonding layer, the second connection structure is exposed to a surface of the second bonding layer.

13. The fabrication method of the semiconductor device of claim 11, wherein connecting the first connection structure with the second connection structure by bonding comprises:
disposing an electromagnetic induction heater at peripheries of the first bonding layer and the second bonding layer; and
starting the electromagnetic induction heater to connect the first connection structure with the second connection structure by bonding.

14. The fabrication method of the semiconductor device of claim 13, wherein the electromagnetic induction heater comprises a coil assembly, alternating current is set within coils in the coil assembly, the coil assembly generates magnetic field perpendicular to the first bonding layer.

15. The fabrication method of the semiconductor device of claim 14, wherein the coil assembly comprises a first winding area and second winding areas located on two sides of the first winding area, wherein the first winding area corresponds to the first bonding layer, a coil density within the first winding area is greater than a coil density within the second winding areas.

16. The fabrication method of the semiconductor device of claim 11, wherein providing the first die and the second die comprises:
providing a first wafer comprising a plurality of the first die,
wherein a plurality of the first metal ring are disposed around the plurality of the first die; and
wherein providing the first wafer comprises:
providing a first dielectric layer, the first dielectric layer connecting a plurality the first bonding layer of the plurality of the first die,
wherein the plurality of the first metal ring are disposed in the first dielectric layer and the plurality of the first bonding layer.

17. The fabrication method of the semiconductor device of claim 11, wherein in providing the plurality of the first die and a plurality of the second die, the plurality of the second die further comprise second metal rings that are exposed to surfaces of the plurality of the second bonding layer, each of the second metal rings is disposed as being closed around at least one of a plurality of the second connection structure.

18. The fabrication method of the semiconductor device of claim 17, wherein providing the first die and the second die comprises:
providing a second wafer comprising a plurality of the second die,
wherein a plurality of the second metal ring are disposed around the plurality of the second die; and
wherein providing the second wafer comprises:
providing a second dielectric layer, the second dielectric layer connecting a plurality of the second bonding layer of the plurality of the second die,
wherein a plurality of the second metal ring are disposed in the second dielectric layer and the plurality of the second bonding layer.

19. The fabrication method of the semiconductor device of claim 17, wherein in disposing the first bonding layer and the second bonding layer in face-to-face manner, with the first connection structure and the second connection structure being disposed in a contraposition contact manner, an orthographic projection of the first metal ring on the second die at least partially overlaps with the second metal ring.

20. A semiconductor apparatus, comprising:
an electromagnetic induction heater configured to surround a semiconductor device in a bonding process; and
a first die including a first bonding layer, wherein a first metal ring is disposed around a first connection structure.
